(19) United States
(12) Patent Application Publication
(10) Pub. No.: US 2020/0135873 A1
(43) Pub. Date: Apr. 30, 2020

(54) DEVICE VARIATION CONTROL OF VERTICAL TRANSPORT FIN FIELD EFFECT TRANSISTOR DEVICES BY SELECTIVE OXIDE DEPOSITION FOR SHALLOW TRENCH ISOLATION FORMATION

(71) Applicant: INTERNATIONAL BUSINESS MACHINES CORPORATION, Armonk, NY (US)

(72) Inventors: Heng Wu, Guilderland, NY (US); Kangguo Cheng, Schenectady, NY (US); Chen Zhang, Albany, NY (US); Tenko Yamashita, Schenectady, NY (US); Sanjay C. Mehta, Niskayuna, NY (US)

(21) Appl. No.: 16/174,906

(22) Filed: Oct. 30, 2018

(51) Int. Cl. H01L 29/417; H01L 29/66; H01L 29/78; H01L 29/06; H01L 21/762; H01L 21/8234

(52) U.S. Cl. CPC H01L 29/41791; H01L 29/66795; H01L 29/785; H01L 29/41741; H01L 21/823487; H01L 29/0653; H01L 21/76224; H01L 21/823431; H01L 21/823481; H01L 29/7827

(57) ABSTRACT

A method of forming an isolation region is provided. The method includes forming a bottom source/drain layer on a substrate, forming an isolation trench through the bottom source/drain layer into the substrate, and filling the isolation trench using a selective oxide deposition, wherein the top surface of the deposited oxide is aligned with a top edge of the bottom source/drain layer.

### BACKGROUND

### Technical Field

The present invention generally relates to fin field effect transistor devices, and more particularly to shallow trench isolation formation for vertical transport fin field effect transistor devices.

### Description of the Related Art

A Field Effect Transistor (FET) typically has a source, a channel, and a drain, where current flows from the source to the drain, and a gate that controls the flow of current through the device channel. Field Effect Transistors (FETs) can have a variety of different structures, for example, FETs have been fabricated with the source, channel, and drain formed in the substrate material itself, where the current flows horizontally (i.e., in the plane of the substrate), and FinFETs have been formed with the channel extending outward from the substrate, but where the current also flows horizontally from a source to a drain. The channel for the FinFET can be an upright slab of thin rectangular silicon (Si), commonly referred to as the fin with a gate on the fin, as compared to a MOSFET with a single gate parallel with the plane of the substrate. Depending on the doping of the source and drain, an n-FET or a p-FET can be formed. Two FETs also can be coupled to form a complementary metal oxide semiconductor (CMOS) device, where a p-channel MOSFET and n-channel MOSFET are electrically coupled together.

### SUMMARY

In accordance with an embodiment of the present invention, a method of forming an isolation region is provided. The method includes forming a bottom source/drain layer on a substrate, forming an isolation trench through the bottom source/drain layer into the substrate, and filling the isolation trench using a selective oxide deposition, wherein the top surface of the deposited oxide is aligned with a top edge of the bottom source/drain layer.

In accordance with another embodiment of the present invention, a method of forming an isolation region is provided. The method includes forming two or more vertical fins on a semiconductor substrate, wherein a separate fin template is on a top surface of each of the two or more vertical fins. The method further includes forming a bottom source/drain layer on the semiconductor substrate, wherein the bottom source/drain layer is a semiconductor material, and forming a fin liner on the sidewalls of the two or more vertical fins. The method further includes forming a bottom spacer layer on the bottom source/drain layer, wherein the bottom spacer layer is a dielectric material. The method further includes forming an isolation trench through the bottom spacer layer and the bottom source/drain layer into the semiconductor substrate between two of the two or more vertical fins, and filling the isolation trench using a selective oxide deposition that deposits a silicon oxide (SiO) on the exposed surfaces of the semiconductor materials.

In accordance with yet another embodiment of the present invention, a vertical transport fin field effect transistor device is provided. The vertical transport fin field effect transistor device includes two vertical fins on a substrate, a bottom source/drain layer on the substrate, and a bottom spacer layer on the bottom source/drain layer. The vertical transport fin field effect transistor device further includes an isolation trench between the two vertical fins, wherein the isolation trench extends through the bottom spacer layer and the bottom source/drain layer, and a dielectric fill in the isolation trench, wherein the dielectric fill fills the isolation trench up to the bottom edge of the bottom spacer layer, such that a gap remains between adjacent sections of the bottom spacer layer.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a cross-sectional side view showing a bottom source/drain layer and a plurality of vertical fins on a substrate with a fin template on each of the vertical fins, and a fin liner on the vertical fins and fin templates, in accordance with an embodiment of the present invention;

FIG. 2 is a cross-sectional side view along the long axis of a vertical fin showing a bottom source/drain layer, a fin template on the vertical fin, and a fin liner on the vertical fin and fin template, in accordance with an embodiment of the present invention;

FIG. 3 is a cross-sectional side view showing a bottom spacer layer formed on the bottom source/drain layer and the fin liner, in accordance with an embodiment of the present invention;

FIG. 4 is a cross-sectional side view showing an isolation trench formed into the substrate through the bottom spacer layer and bottom source/drain layer, in accordance with an embodiment of the present invention;

FIG. 5 is a cross-sectional side view along the long axis of a vertical fin showing an isolation trench formed into the substrate through the bottom spacer layer and bottom source/drain layer on either end of the vertical fin, in accordance with an embodiment of the present invention;

FIG. 6 is a cross-sectional side view showing a dielectric fill formed in the isolation trench between an adjacent pair of vertical fins, in accordance with an embodiment of the present invention;

FIG. 7 is a cross-sectional side view along the long axis of a vertical fin showing a dielectric fill formed in the isolation trench on either end of the vertical fin, in accordance with an embodiment of the present invention;

FIG. 8 is a cross-sectional side view showing gate structures, a top spacer layer, and top source/drains formed on the vertical fins, in accordance with an embodiment of the present invention;

FIG. 9 is a cross-sectional side view showing a bottom source/drain layer and a plurality of vertical fins on a substrate with a fin template on each of the vertical fins, and a fin liner on the vertical fins and fin templates, in accordance with another embodiment of the present invention;

FIG. 10 is a cross-sectional side view showing a protective layer formed on the bottom source/drain layer and fin liner, in accordance with another embodiment of the present invention;

FIG. 11 is a cross-sectional side view along the long axis of a vertical fin showing the protective layer on the bottom source/drain layer and fin liner, in accordance with another embodiment of the present invention;

FIG. 12 is a cross-sectional side view along the long axis of a vertical fin showing a masking block on a portion of the protective layer and over a portion of the vertical fin, in accordance with another embodiment of the present invention;

FIG. 13 is a cross-sectional side view along the long axis of a vertical fin showing an isolation trench formed into the substrate through the protective layer and bottom source/drain layer on either side of the vertical fin, in accordance with another embodiment of the present invention;

FIG. 14 is a cross-sectional side view showing an isolation trench formed into the substrate through the protective layer and bottom source/drain layer adjacent to each of a pair of vertical fins, in accordance with another embodiment of the present invention;

FIG. 15 is a cross-sectional side view along the long axis of a vertical fin showing a dielectric fill formed in the isolation trench on either end of the vertical fin, in accordance with another embodiment of the present invention;

FIG. 16 is a cross-sectional side view showing a dielectric fill formed in the isolation trench on opposite sides of each of the pair of vertical fins, in accordance with another embodiment of the present invention;

FIG. 17 is a cross-sectional side view showing a dielectric fill in an isolation trench and on the bottom source/drain layer, in accordance with yet another embodiment of the present invention;

FIG. 18 is a cross-sectional side view showing the dielectric fill removed from the bottom source/drain layer, while remaining in the isolation trench to form a shallow trench isolation region, in accordance with yet another embodiment of the present invention;

FIG. 19 is a cross-sectional side view showing a shielding liner on the protective layer and on the sidewalls of the isolation trench, in accordance with yet another embodiment of the present invention; and

FIG. 20 is a cross-sectional side view showing a dielectric fill formed in the isolation trench, where a portion of the shielding liner has been removed from the bottom surface of the isolation trench, in accordance with yet another embodiment of the present invention.

### DETAILED DESCRIPTION

Embodiments of the present invention provide an approach using selective deposition to form shallow trench isolation (STI) regions in a substrate, where the dielectric fill has a consistent height. The selective deposition of SiO₂ can be used to deposit SiO₂ only on silicon (Si) terminated surfaces instead of on dielectric surfaces, for example, SiN or other non-silicon oxide materials, to enable the STI formation. The deposition can incorporate the deposition of an oxide on certain materials, such as SiO₂ on SiO₂ instead of Al₂O₃, or SiO₂ on Si instead of SiN. Selective deposition of materials is an emerging technique in semiconductor manufacturing. The selective deposition uses cyclic atomic layer deposition (ALD) with selective inhibition (such as Acetyl Acetone) flow/Purge+bis(diethylamino)silane (BDEAS) step as the Si precursor (Si precursor)/Purge+O₂ plasma/purge. The temperature of the selectively deposition can be lower than 200° C.

Embodiments of the present invention provide semiconductor devices separated by shallow trench isolation regions having uniform dielectric heights in the isolation trenches. Due to the selective nature of the deposition process, a formed STI oxide can be self-aligned with the STI trench edge to enable much better device uniformity and simplify the overall process flow. The interface between a semiconductor (e.g., Si) and dielectric (e.g., SiN) layer can be used to consistently self-align the top surface of the dielectric fill with the top semiconductor edge.

Exemplary applications/uses to which the present invention can be applied include, but are not limited to: logic devices (e.g., NAND gate circuits, NOR gate circuits, inverters, etc.) and memory devices (e.g., static random access memory (SRAM), dynamic access memory (DRAM).

It is to be understood that aspects of the present invention will be described in terms of a given illustrative architecture; however, other architectures, structures, substrate materials and process features and steps can be varied within the scope of aspects of the present invention.

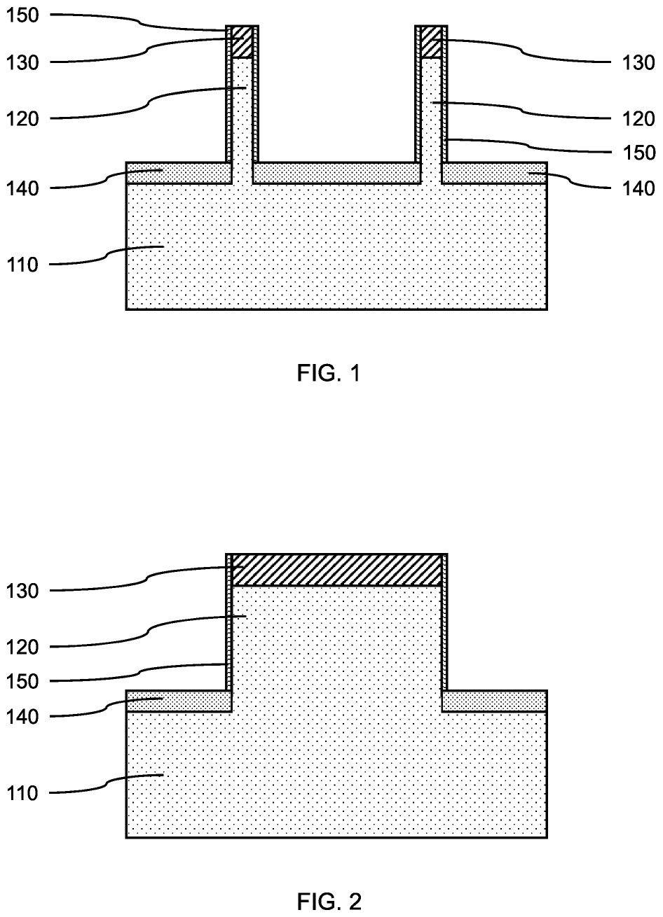

Referring now to the drawings in which like numerals represent the same or similar elements and initially to FIG. 1, a cross-sectional side view of a bottom source/drain layer and a plurality of vertical fins on a substrate with a fin template on each of the vertical fins, and a fin liner on the vertical fins and fin templates is shown, in accordance with an embodiment of the present invention.

In one or more embodiments, a substrate 110 can be, for example, a single crystal semiconductor material wafer or a semiconductor-on-insulator stacked wafer. The substrate 110 can include a support layer that provides structural support, and an active semiconductor layer that can form devices. An insulating layer (e.g., a buried oxide (BOX) layer) may be between the active semiconductor layer and the support layer to form a semiconductor-on-insulator substrate (SeOI) (e.g., a silicon-on-insulator substrate (SOI)).

In one or more embodiments, the substrate 110 or an active semiconductor layer can be a crystalline semiconductor, for example, a IV or IV-IV semiconductor (e.g., silicon (Si), silicon carbide (SiC), silicon-germanium (SiGe), germanium (Ge)) or a III-V semiconductor (e.g., gallium-arsenide (GaAs), indium-phosphide (InP), indium-antimonide (InSb)). In various embodiments, the substrate 110 can be a single crystal wafer.

In one or more embodiments, one or more vertical fins 120 can be formed on the substrate 110. The vertical fins 120 can be formed by a multiple patterning fabrication process, for example, a sidewall image transfer (SIT) process, a self-aligned double patterning (SADP) process, self-aligned triple patterning (SATP) process, or a self-aligned quadruple patterning (SAQP). The vertical fins 120 may be formed by a direct write process or double patterning process using, for example, immersion lithography, extreme ultraviolet lithography, or x-ray lithography. The fin templates 130 can be formed from a fin template layer previously formed on the substrate, as part of the patterning process.

In various embodiments, the widths of the semiconductor vertical fin(s) 120 can be in a range of about 5 nanometers (nm) to about 15 nm, or about 6 nm to about 10 nm, or about 6 nm to about 8 nm, although other widths are also contemplated.

In various embodiments, the height of the semiconductor vertical fin(s) 120 can be in a range of about 20 nanometers (nm) to about 100 nm, or about 30 nm to about 50 nm, although other heights are also contemplated. Although the vertical fins 120 are depicted in the figures perpendicular to the substrate 110 (i.e., having a 90 degree angle), the fins can have a tapered sidewall that does not meet the substrate at a right angle (i.e., not exactly 90 degree). The top surface of the vertical fins 120 may not be perfectly flat or rectangular, but may have a convex curved surface. The substrate surface can have a curved (recessed) profile between the vertical fins.

In various embodiments, a fin template 130 can be formed on each of the vertical fins as part of a lithography or patterning process, where the fin templates 130 can be a hardmask material, including, but not limited to, silicon oxide (SiO), silicon nitride (SiN), silicon oxynitride (SiON), silicon carbonitride (SiCN), silicon boronitride (SiBN), silicon borocarbide (SiBC), silicon boro carbonitride (SiBCN), or combinations thereof.

In one or more embodiments, a bottom source/drain layer 140 can be formed on a substrate 110, where the bottom source/drain layer 140 can be formed by implantation and/or an epitaxial or heteroepitaxial growth process, for example, molecular beam epitaxy (MBE), liquid phase epitaxy (LPE), or gas phase epitaxy (GPE). The bottom source/drain layer 140 can be doped to be an n-type bottom source/drain layer or a p-type bottom source/drain layer, where the dopant(s) can be introduced in situ (i.e., during formation of a layer) or ex situ (i.e., after formation of a layer). In various embodiments, n-type dopants can be, for example, phosphorus (P) or arsenic (As), and p-type dopants can be, for example, boron (B) or gallium (Ga). In various embodiments, the bottom source/drain layer 140 can be a semiconductor material, including, but not limited to n-type (e.g., P or As) doped silicon (Si) or p-type (e.g., B) doped silicon-germanium (SiGe). The bottom source/drain layer 140 can be the same semiconductor material as the substrate 110 or a different semiconductor material heteroepitaxially grown on the substrate. In various embodiments, the bottom source/drain layer 140 can be formed after formation of the vertical fin(s) 120, where the bottom source/drain layer can be formed by dopant implantation.

In various embodiments, the bottom source/drain layer 140 can have a thickness in a range of about 10 nm to about 40 nm, or about 20 nm to about 30 nm, although other thicknesses are also contemplated.

In one or more embodiments, a fin liner 150 can be formed on the vertical fin(s) 120 and bottom source/drain layer 140, where the fin liner 150 can be formed by a conformal deposition, for example, atomic layer deposition (ALD), plasma enhanced ALD (PEALD), low pressure chemical vapor deposition, (LPCVD), or a combination thereof.

In various embodiments, the fin liner 150 can have a thickness in a range of about 2 nm to about 6 nm, or about 3 nm to about 5 nm, although other thicknesses are also contemplated.

In various embodiments, the fin liner 150 can be hardmask material, including, but not limited to, silicon oxide (SiO), silicon nitride (SiN), silicon oxynitride (SiON), silicon carbonitride (SiCN), silicon boronitride (SiBN), silicon borocarbide (SiBC), silicon boro carbonitride (SiBCN), or combinations thereof. The fin liner 150 can be a different hardmask material from the fin templates 130, so the fin liner can be selectively removed.

In various embodiments, a portion of the fin liner 150 on the bottom source/drain layer 140 and a portion of the fin liner on the top surfaces of the fin templates 130 can be removed, where the portion of the fin liner 150 can be removed using a selective, directional etch, for example, a reactive ion etch (RIE).

FIG. 2 is a cross-sectional side view along the long axis of a vertical fin showing a bottom source/drain layer, a fin template on the vertical fin, and a fin liner on the vertical fin and fin template, in accordance with an embodiment of the present invention.

In one or more embodiments, the fin liner 150 can wrap around four sides of the vertical fins 120. In various embodiments, the bottom source/drain layer 140 can be around the vertical fins.

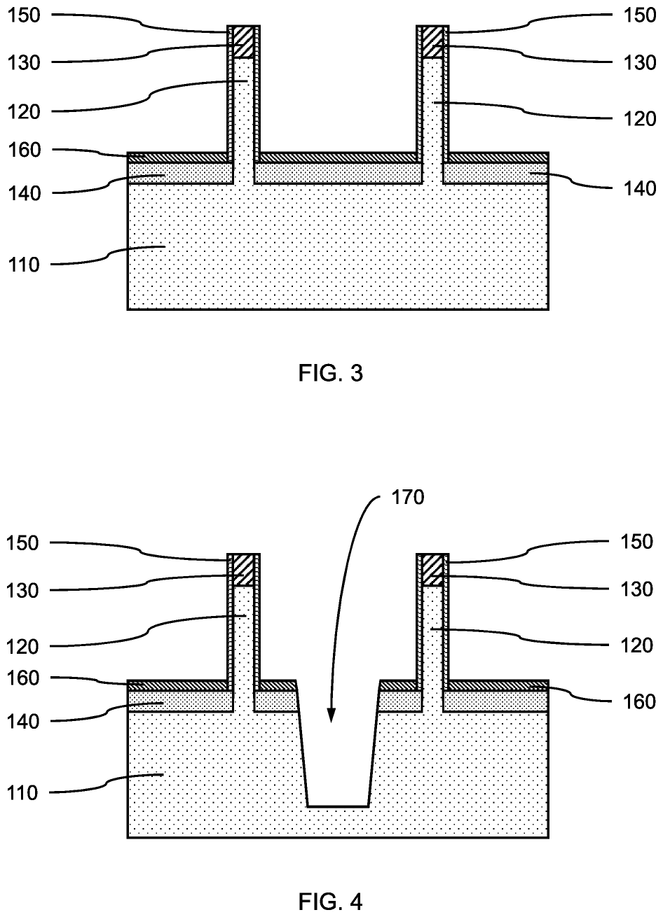

FIG. 3 is a cross-sectional side view showing a bottom spacer layer formed on the bottom source/drain layer and the fin liner, in accordance with an embodiment of the present invention.

In one or more embodiments, a bottom spacer layer 160 can be formed on the bottom source/drain layer 140 and on a lower portion of the fin liner 150, where the bottom spacer layer 160 can be formed by a directional deposition to a predetermined thickness, for example, by a high density plasma (HDP) or gas cluster ion beam (GCIB), or by a blanket deposition, for example, chemical vapor deposition (CVD) or plasma enhanced CVD (PECVD) and etched back to an intended thickness, for example, using an isotropic etch (e.g., wet chemical etch, dry plasma etch).

In various embodiments, the bottom spacer layer 160 can have a thickness in a range of about 3 nm to about 10 nm, or about 5 nm to about 7 nm, although other thicknesses are also contemplated.

In various embodiments, the bottom spacer layer 160 can be a dielectric material, including, but not limited to, silicon oxide (SiO), silicon nitride (SiN), silicon oxynitride (SiON), silicon carbonitride (SiCN), silicon boronitride (SiBN), silicon borocarbide (SiBC), silicon boro carbonitride (SiBCN), or combinations thereof. The bottom spacer layer 160 can be a material different from the fin liner 150 and fin templates 130 to allow selective removal.

FIG. 4 is a cross-sectional side view showing an isolation trench formed into the substrate through the bottom spacer layer and bottom source/drain layer, in accordance with an embodiment of the present invention.

In one or more embodiments, an isolation trench 170 can be formed into the substrate 110 through the bottom spacer layer 160 and bottom source/drain layer 140. The isolation trench 170 can be formed by filling the space around the vertical fins 120 with a dummy fill layer and patterning the dummy fill layer through lithographic techniques and etching. The isolation trench 170 can be formed by a sequence of selective directional etches through the bottom spacer layer 160, bottom source/drain layer 140, and substrate 110.

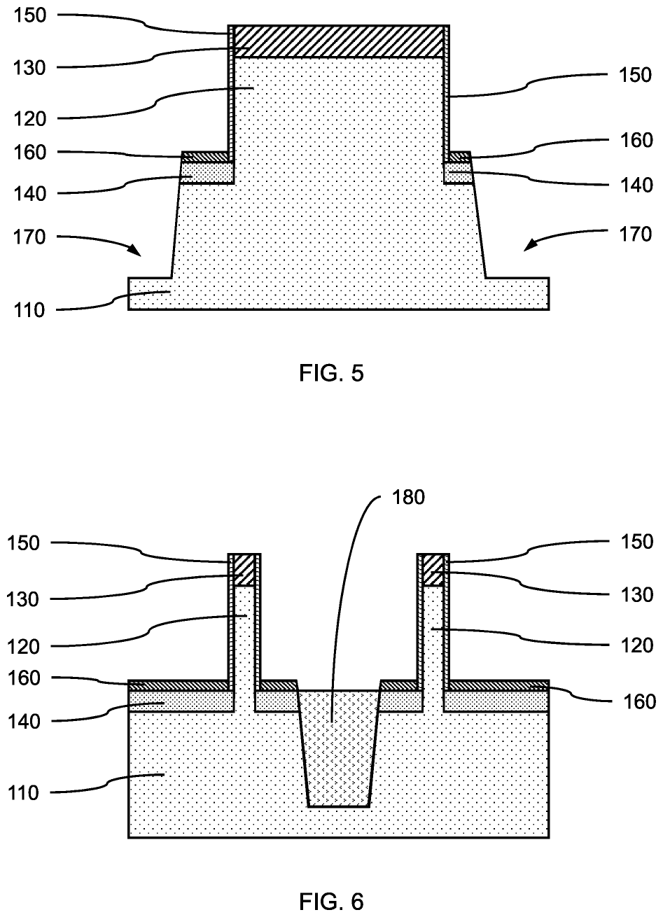

FIG. 5 is a cross-sectional side view along the long axis of a vertical fin showing an isolation trench formed into the substrate through the bottom spacer layer and bottom source/drain layer on either end of the vertical fin, in accordance with an embodiment of the present invention.

In one or more embodiments, the isolation trench 170 can be formed around each of the vertical fins 120, where the isolation trench 170 can physically and electrically separate adjacent vertical fins for forming independent vertical transport fin field effect transistor (VT FinFET) devices. In various embodiments, the distance of the isolation trench 170 from opposite end walls of the vertical fins 120 can be asymmetric, such that a larger plateau is adjacent to a vertical fin on one side than on the other side.

FIG. 6 is a cross-sectional side view showing a dielectric fill formed in the isolation trench between an adjacent pair of vertical fins, in accordance with an embodiment of the present invention.

In one or more embodiments, a dielectric fill 180 can be formed in the isolation trench, where the isolation trench 170 can be filled with a dielectric material to form an isolation region. In various embodiments, the isolation trench 170 can be filled using a selective oxide deposition, where a silicon oxide (SiO) can be selectively formed on exposed surfaces of a semiconductor material, but does not form on the surfaces of the dielectric materials (e.g., hardmask materials). In various embodiments, the silicon oxide (SiO) forms preferentially on single crystal silicon (Si) surfaces of the substrate 110 and bottom source/drain layer 140, and not on a silicon nitride (SiN) bottom spacer layer 160.

In various embodiments, the dielectric fill 180 can fill in the isolation trench 170 up to the bottom edge of the bottom spacer layer 160, such that a gap can remain between adjacent sections of the bottom spacer layer 160.

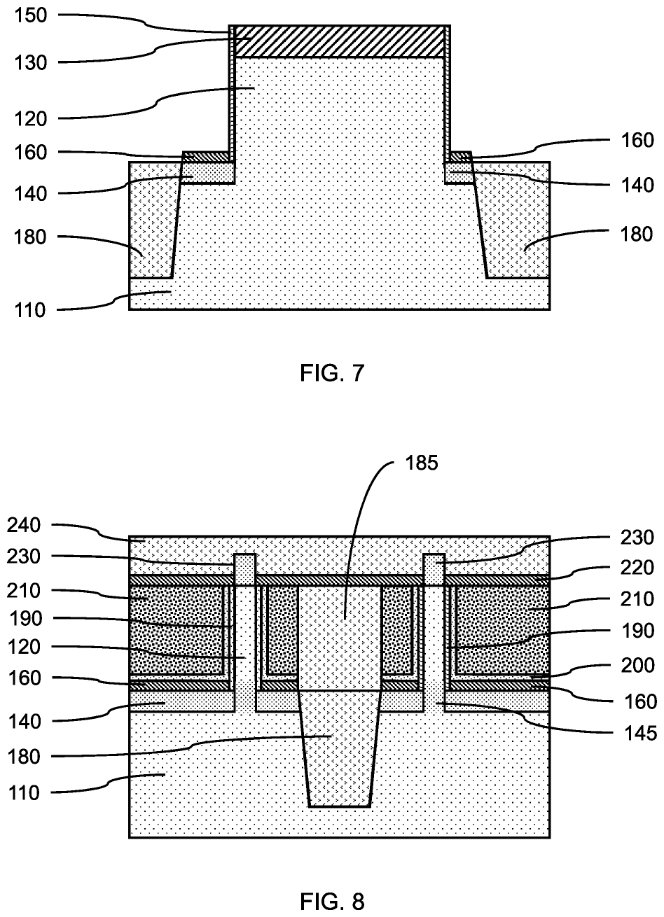

FIG. 7 is a cross-sectional side view along the long axis of a vertical fin showing a dielectric fill formed in the isolation trench on either end of the vertical fin, in accordance with an embodiment of the present invention.

In one or more embodiments, the dielectric fill 180 formed in the isolation trench 170 can be on either side of the vertical fin 120. The dielectric fill 180 can surround one or more of the vertical fins 120, where the dielectric fill 180 can physically and electrically separate adjacent vertical fins. The dielectric fill 180 formed in the isolation trench 170 can be self-aligned with the top edge of the bottom source/drain layer 140 adjoining the bottom spacer layer 160 in the isolation trench 170 using a selective deposition.

FIG. 8 is a cross-sectional side view showing gate structures, a top spacer layer, and top source/drains formed on the vertical fins, in accordance with an embodiment of the present invention.

In one or more embodiments, the fin liner 150 and fin templates 130 can be removed to expose surfaces of the vertical fins 120, and gate structures, a top spacer layer 220, and top source/drains 230 can be formed on the vertical fins. The gate structures can include a gate dielectric layer 190 that can replace the fin liner 150, a work function layer 200 formed on the gate dielectric layer, and a conductive gate fill 210 formed on the work function layer.

In various embodiments, the gate dielectric layer 190 can be a dielectric material, including, but not limited to, silicon oxide (SiO), silicon nitride (SiN), silicon oxynitride (SiON), silicon boronitride (SiBN), silicon boro carbonitride (SiBCN), silicon carbonitride (SiCN), silicon oxycarbonitride (SiOCN), a high-k dielectric, and combinations thereof. Examples of high-k materials include but are not limited to metal oxides, such as, hafnium oxide (HfO), hafnium silicon oxide (HfSiO), hafnium silicon oxynitride (HfSiON), lanthanum oxide (LaO), lanthanum aluminum oxide (LaAlO), zirconium oxide (ZrO), zirconium silicon oxide (ZrSiO), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), lead scandium tantalum oxide (PbScTaO), and lead zinc niobate (PbZnNbO). The high-k material may further include dopants such as lanthanum, aluminum, magnesium, or combinations thereof.

In various embodiments, the gate dielectric layer 190 can have a thickness in a range of about 1 nm to about 3 nm, or about 2 nm, although other thicknesses are also contemplated.

In various embodiments, the work function layer 200 can be a conducting metallic nitride or carbide compound material, for example, tantalum nitride (TaN), titanium nitride (TiN), tantalum carbide (TaC), titanium carbide (TiC), titanium aluminum carbide (TiAlC), and combinations thereof.

In various embodiments, the conductive gate fill 210 can be a metal (e.g., tungsten (W), titanium (Ti), tantalum (Ta), ruthenium (Ru), hafnium (Hf), zirconium (Zr), cobalt (Co), nickel (Ni), copper (Cu), aluminum (Al), platinum (Pt), tin (Sn), silver (Ag), gold (Au), a conducting metallic compound material (e.g., tantalum nitride (TaN), titanium nitride (TiN), tantalum carbide (TaC), titanium carbide (TiC), titanium aluminum carbide (TiAlC), tungsten silicide (WSi), tungsten nitride (WN), ruthenium oxide (RuO₂), cobalt silicide (CoSi), nickel silicide (NiSi)), transition metal aluminides (e.g. Ti₃Al, ZrAl), TaC, TaMgC, or any suitable combination of these materials.

The gate dielectric layer 190, work function layer 200, and conductive gate fill 210 can form an active gate structure on one or more of the vertical fin(s) 120 and the bottom spacer layer 160.

In various embodiments, a suitable patterning technique, such as lithography followed by an etch process, can be used to remove the gate material from predetermined regions of the substrate 110, where the predetermined regions of the substrate can be above the dielectric fill 180 in the isolation trench(es) 170 forming an isolation region. A dielectric material can fill the openings formed above the dielectric fill 180 to form a dielectric separation region 185 that physically and electrically separates adjacent gate structures.

In one or more embodiments, a lower extension region 145 can be formed in a lower portion of the vertical fins 120, where the lower extension region 145 can be formed by a heat treatment to diffuse dopants from the bottom source/drain layer 140 into the adjoining vertical fins 120. The lower extension region 145 can be adjacent to the bottom spacer layer 160, and may extend above the top surface of the bottom spacer layer to overlap a gate structure.

In one or more embodiments, top source/drains 230 can be formed by epitaxial or heteroepitaxial growth on the top surface of the vertical fins 120. The top source/drains 230 can be an n-doped or p-doped semiconductor material, where the dopant type of the top source/drains 230 can match the dopant type of the bottom source/drain layer 140. The semiconductor material can be the same as or different from the semiconductor material of the vertical fins 120 and/or the bottom source/drain layer 140.

In one or more embodiments, an interlayer dielectric (ILD) layer 240 can be formed on the top spacer layer 220. In various embodiments, the top spacer layer 220 can be a dielectric material, including, but not limited to, silicon oxide (SiO), silicon nitride (SiN), silicon oxynitride (SiON), silicon boronitride (SiBN), silicon boro carbonitride (SiBCN), silicon carbonitride (SiCN), silicon oxycarbonitride (SiOCN), a high-k dielectric, and combinations thereof.

In various embodiments the interlayer dielectric (ILD) layer 240 can be a dielectric material, including, but not limited to, silicon oxide (SiO) or a low-k material. A low-k dielectric material can include, but not be limited to, carbon doped silicon oxide (SiO:C), fluorine doped silicon oxide (SiO:F), polymeric material, for example, tetraethyl orthosilicate (TEOS), hydrogen silsesquioxane (HSQ), methylsilsesquioxane (MSQ), silicon carbide (SiC), silicon oxynitride (SiON), silicon-carbon-nitride (SiCN), boron nitride (BN), silicon boron nitride (SiBN), silicon boron carbonitride (SiBCN), silicon oxycabonitride (SiOCN), silicon oxide (SiO), and combinations thereof.

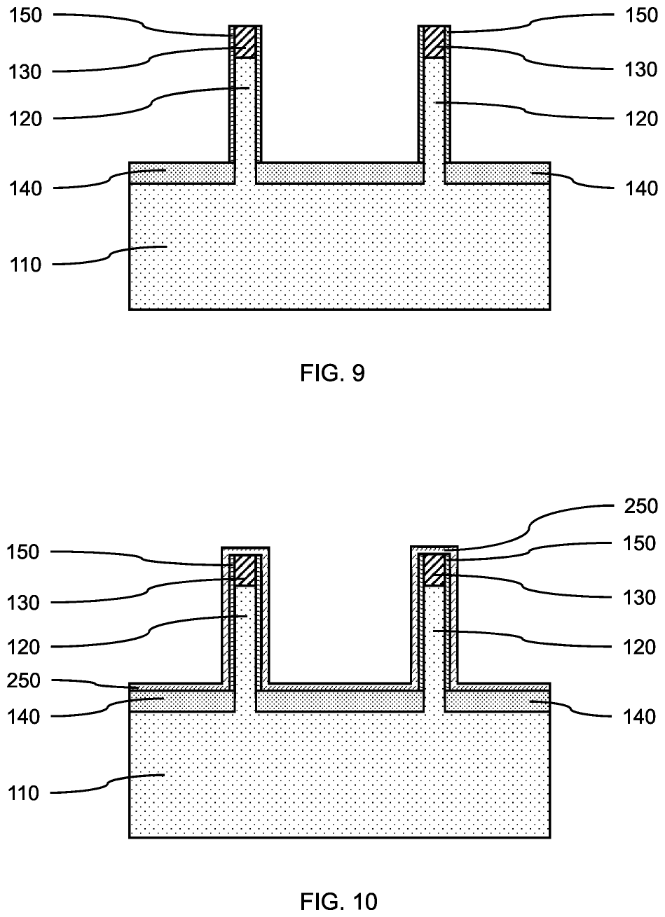

FIG. 9 is a cross-sectional side view showing a bottom source/drain layer and a plurality of vertical fins on a substrate with a fin template on each of the vertical fins, and a fin liner on the vertical fins and fin templates, in accordance with another embodiment of the present invention.

In one or more embodiments, a bottom source/drain layer and a plurality of vertical fins can be formed on a substrate with a fin template on each of the vertical fins, as described for FIG. 1.

FIG. 10 is a cross-sectional side view showing a protective layer formed on the bottom source/drain layer and fin liner, in accordance with another embodiment of the present invention.

In one or more embodiments, a protective layer 250 can be formed on the exposed surfaces of the bottom source/drain layer 140 and fin liner 150, where the protective layer 250 can be formed by a conformal deposition (e.g., ALD, PEALD, LPCVD).

In various embodiments, the protective layer 250 can have a thickness in a range of about 3 nm to about 10 nm, or about 5 nm to about 7 nm, although other thicknesses are also contemplated.

In various embodiments, the protective layer 250 can be a dielectric material, including, but not limited to, silicon oxide (SiO), silicon nitride (SiN), silicon oxynitride (SiON), silicon carbonitride (SiCN), silicon boronitride (SiBN), silicon borocarbide (SiBC), silicon boro carbonitride (SiBCN), or combinations thereof. The protective layer 250 can be a material different from the fin templates 130 and fin liner 150 to allow selective removal.

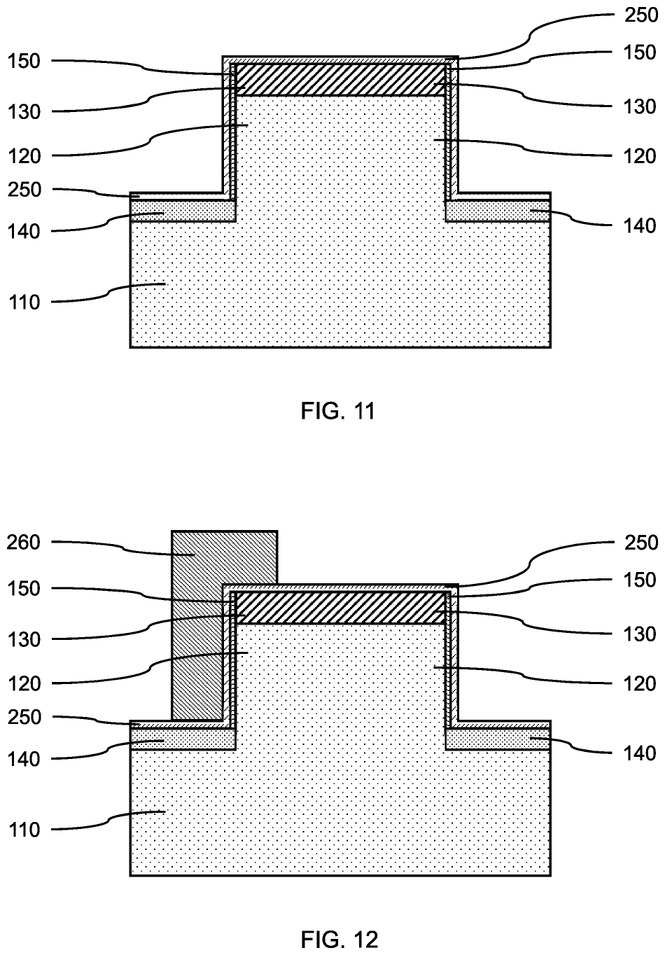

FIG. 11 is a cross-sectional side view along the long axis of a vertical fin showing the protective layer on the bottom source/drain layer and fin liner, in accordance with another embodiment of the present invention.

In one or more embodiments, the protective layer 250 can cover the vertical fin(s) 120, fin template(s) 130, fin liner 150, and bottom source/drain layer 140, where the protective layer 250 can be around the vertical fin 120.

FIG. 12 is a cross-sectional side view along the long axis of a vertical fin showing a masking block on a portion of the protective layer and over a portion of the vertical fin, in accordance with another embodiment of the present invention.

In one or more embodiments, a masking block 260 can be formed on a portion of the protective layer 250 and over a portion of the vertical fin 120, where the masking block 260 can be formed by a blanket deposition (e.g., CVD, PECVD, spin-on), and masking, lithography, and etching used to pattern the masking block 260.

In various embodiments, the masking block 260 can be a hardmask material, including, but not limited to, silicon oxide (SiO), silicon nitride (SiN), silicon oxynitride (SiON), silicon carbonitride (SiCN), silicon boronitride (SiBN), silicon borocarbide (SiBC), silicon boro carbonitride (SiBCN), or combinations thereof, which can be selectively removed.

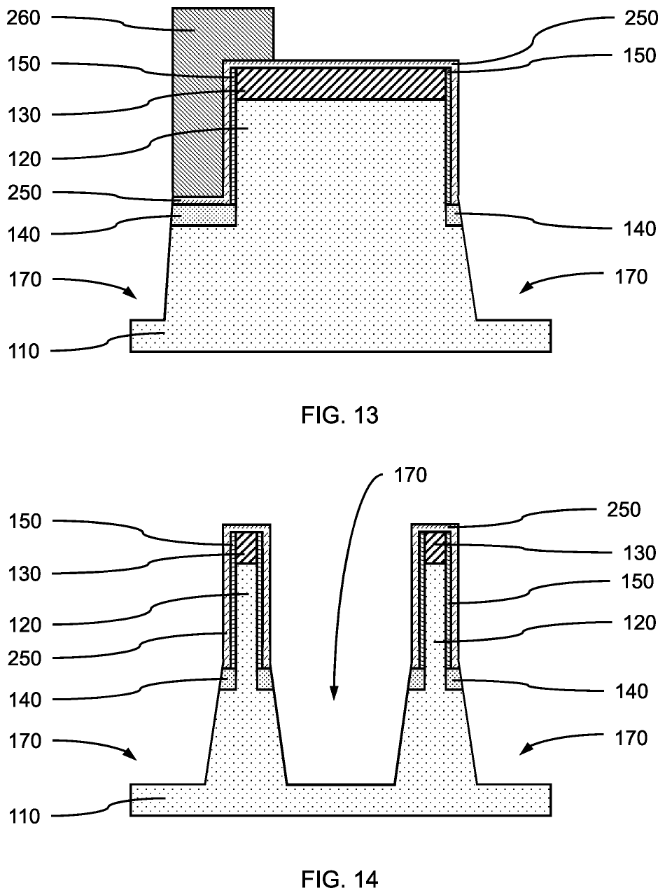

FIG. 13 is a cross-sectional side view along the long axis of a vertical fin showing an isolation trench formed into the substrate through the protective layer and bottom source/drain layer on either side of the vertical fin, in accordance with another embodiment of the present invention.

In one or more embodiments, an isolation trench 170 can be formed into the substrate 110 through the protective layer 250 and bottom source/drain layer 140. The isolation trench 170 can be formed by a sequence of selective directional etches (e.g., RIE) through the protective layer 250, bottom source/drain layer 140, and substrate 110. The isolation trench 170 can be offset from the end walls of the vertical fin by the thickness of the protective layer 250 on one side and by the width of the masking block 260 extending over the vertical fin end on an opposite side, where the offset can form a ledge with a width sufficient to form a source/drain contact to the source/drain layer 140.

FIG. 14 is a cross-sectional side view showing an isolation trench formed into the substrate through the protective layer and bottom source/drain layer adjacent to each of a pair of vertical fins, in accordance with another embodiment of the present invention.

In one or more embodiments, an isolation trench 170 can be formed into the substrate 110 through the protective layer 250 and bottom source/drain layer 140 adjacent to pair of vertical fins, where the isolation trench 170 can physically and electrically separate adjacent vertical fins for forming independent vertical transport fin field effect transistor (VT FinFET) devices.

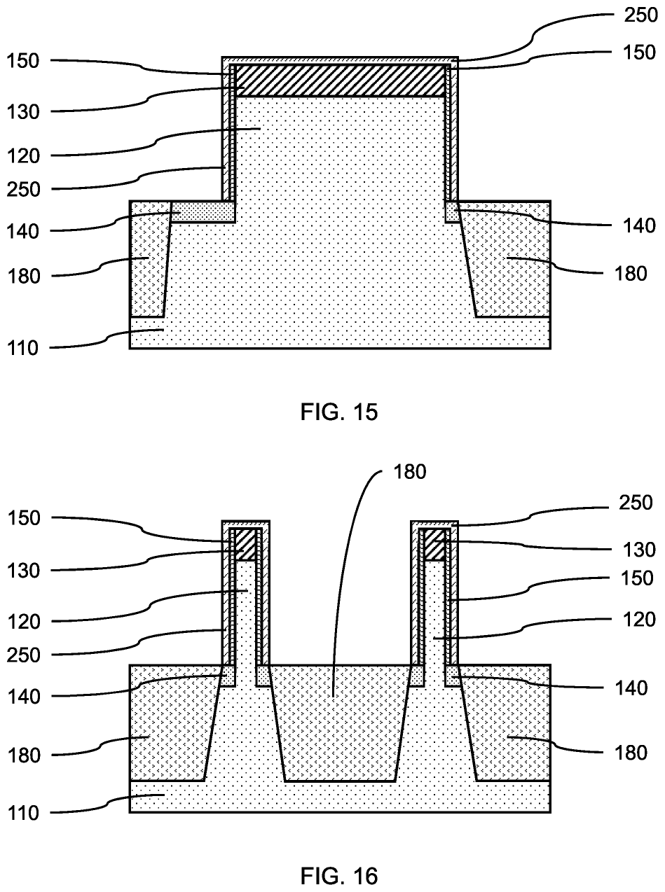

FIG. 15 is a cross-sectional side view along the long axis of a vertical fin showing a dielectric fill formed in the isolation trench on either end of the vertical fin, in accordance with another embodiment of the present invention.

In one or more embodiments, a dielectric fill 180 can be formed in the isolation trench 170, where the isolation trench can be filled with a dielectric material to form an isolation region. In various embodiments, the isolation trench 170 can be filled using a selective oxide deposition, where a silicon oxide (SiO) can be selectively formed on exposed surfaces of a semiconductor material, but does not form on the surfaces of the dielectric materials (e.g., hardmask materials). In various embodiments, the silicon oxide (SiO) forms preferentially on single crystal silicon (Si) surfaces of the substrate 110 and bottom source/drain layer 140. In various embodiments, the dielectric fill 180 can fill in the isolation trench 170 up to the top edge of the bottom source/drain layer 140.

FIG. 16 is a cross-sectional side view showing a dielectric fill formed in the isolation trench on opposite sides of each of the pair of vertical fins, in accordance with another embodiment of the present invention.

In one or more embodiments, the dielectric fill 180 can be formed in the isolation trench 170 on opposite sides of the pair of vertical fins.

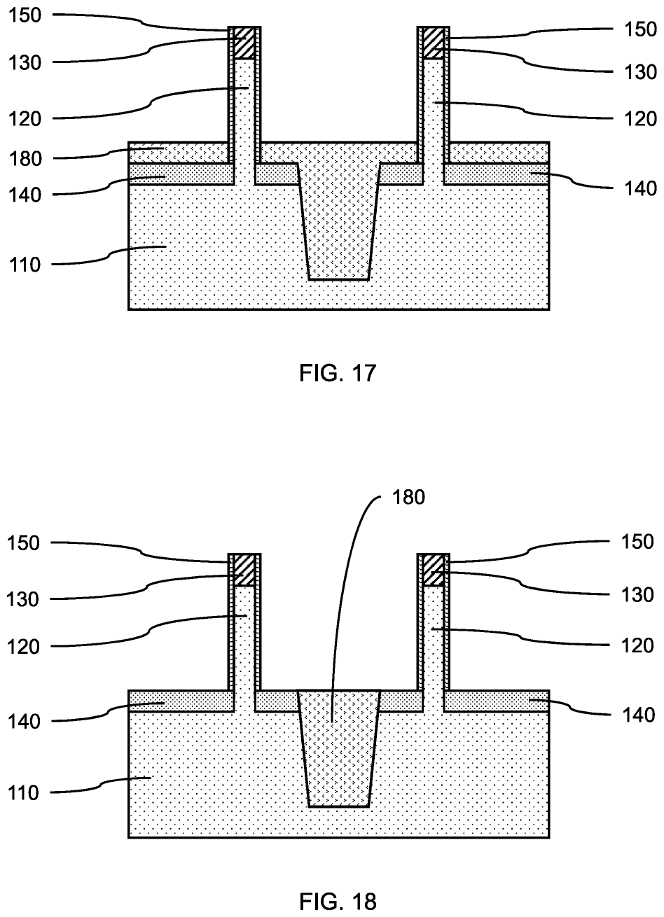

FIG. 17 is a cross-sectional side view showing a dielectric fill in an isolation trench and on the bottom source/drain layer, in accordance with yet another embodiment of the present invention.

In one or more embodiments, a dielectric fill 180 can be formed in the isolation trench 170 and on an exposed surface of the bottom source/drain layer 140. The dielectric fill 180 can be formed using a selective oxide deposition, where a silicon oxide (SiO) can be selectively formed on exposed surfaces of the isolation trench 170 and the bottom source/drain layer 140, but does not form on the surfaces of the fin liner 150 or fin templates 130. In various embodiments, the dielectric fill 180 can fill in the isolation trench 170 up to the top edge of the bottom source/drain layer.

FIG. 18 is a cross-sectional side view showing the dielectric fill removed from the bottom source/drain layer, while remaining in the isolation trench to form a shallow trench isolation region, in accordance with yet another embodiment of the present invention.

In various embodiments, an isotropic etch and/or a directional etch can be used to reduce the height of the dielectric fill 180 to the top surface of the bottom source/drain layer 140 to form an isolation region, where the isolation region can be between a pair of vertical fins 120.

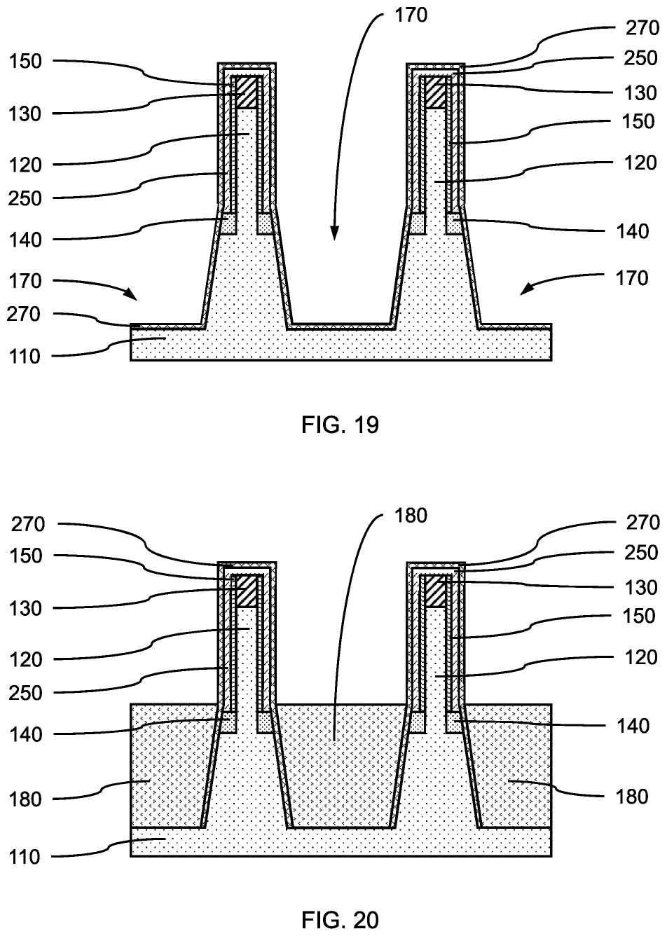

FIG. 19 is a cross-sectional side view showing a shielding liner on the protective layer and on the sidewalls of the isolation trench, in accordance with yet another embodiment of the present invention.

In one or more embodiments, a shielding liner 270 can be formed on the exposed sidewalls of the isolation trench 170 and on the protective layer 250, where the shielding liner 270 can be formed by a conformal deposition. The shielding liner 270 can be a material on which a selective deposition does not deposit the dielectric fill 180.

FIG. 20 is a cross-sectional side view showing a dielectric fill formed in the isolation trench, where a portion of the shielding liner has been removed from the bottom surface of the isolation trench, in accordance with yet another embodiment of the present invention.

In one or more embodiments, a portion of the shielding liner 270 can be removed from the surface of the substrate, where the shielding liner 270 can be removed using a selective, directional etch (e.g., RIE). Portions of the shielding liner 270 can remain on sidewalls of the isolation trench.

In one or more embodiments, a dielectric fill 180 can be formed in the isolation trench 170, where a portion of the shielding liner 270 has been removed to expose semiconductor material at the bottom surface of the isolation trench 170. The dielectric fill 180 can be formed using a selective oxide deposition, where a silicon oxide (SiO) can be selectively formed on the exposed bottom surface of the isolation trench 170, but not on the surfaces of the shielding liner 270.

In various embodiments, additional steps can be performed to form gate structures, tops spacer layers, and top source/drains, as discussed for FIG. 8.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence ref stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

Having described preferred embodiments of a device and method of fabricating a device (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A method of forming an isolation region, comprising:
forming a bottom source/drain layer on a substrate, wherein the substrate and the bottom source/drain layer include a semiconductor material;
forming an isolation trench through the bottom source/drain layer into the substrate; and
filling the isolation trench using a selective oxide deposition, wherein the oxide is selectively deposited on the surfaces of the semiconductor materials but not non-semiconductor materials, and the top surface of the deposited oxide is aligned with a top edge of the bottom source/drain layer.

2. The method of claim 1, further comprising forming a bottom spacer layer on the bottom source/drain layer, wherein the isolation trench goes through the bottom spacer layer.

3. The method of claim 2, wherein the bottom spacer layer is a dielectric material, and wherein the selective oxide deposition selectively forms silicon oxide on the exposed surfaces of the semiconductor materials and not the dielectric material.

4. The method of claim 1, further comprising forming a plurality of vertical fins on the substrate, and foil ling a fin liner on the plurality of vertical fins.

5. The method of claim 4, further comprising forming a protective layer on the bottom source/drain layer and the fin liner, and removing a portion of the protective layer to expose a portion of the underlying bottom source/drain layer.

6. The method of claim 5, wherein the isolation trench extends through the expose portion of the underlying bottom source/drain layer into the substrate.

7. The method of claim 6, wherein the fin liner is a hardmask material selected from the group consisting of silicon oxide (SiO), silicon nitride (SiN), silicon oxynitride (SiON), silicon carbonitride (SiCN), silicon boronitride (SiBN), silicon borocarbide (SiBC), silicon boro carbonitride (SiBCN), and combinations thereof.

8. The method of claim 5, further comprising forming a silicon oxide material on the exposed surfaces of the bottom source/drain layer using the selective oxide deposition.

9. The method of claim 8, further comprising removing the silicon oxide material from the bottom source/drain layer using a selective isotropic etch, wherein a portion of the silicon oxide material remains in the isolation trench.

10. The method of claim 1, further comprising forming a shielding liner on the exposed surfaces of the isolation trench, and removing a portion of the shielding liner from the bottom surface of the isolation trench.

11. A method of forming an isolation region, comprising:
forming two or more vertical fins on a semiconductor substrate, wherein a separate fin template is on a top surface of each of the two or more vertical fins;
forming a bottom source/drain layer on the semiconductor substrate, wherein the bottom source/drain layer is a semiconductor material;
forming a fin liner on the sidewalls of the two or more vertical fins;
forming a bottom spacer layer on the bottom source/drain layer, wherein the bottom spacer layer is a dielectric material;
forming an isolation trench through the bottom spacer layer and the bottom source/drain layer into the semiconductor substrate between two of the two or more vertical fins; and
filling the isolation trench using a selective oxide deposition that deposits a silicon oxide (SiO) on the exposed surfaces of the semiconductor materials but not non-semiconductor materials.

12. The method of claim 11, wherein the substrate and bottom source/drain layer are single crystal silicon, and the bottom spacer layer is a dielectric material selected from the group consisting of silicon oxide (SiO), silicon nitride (SiN), silicon oxynitride (SiON), silicon carbonitride (SiCN), silicon boronitride (SiBN), silicon borocarbide (SiBC), silicon boro carbonitride (SiBCN), and combinations thereof.

13. The method of claim 12, wherein the fin liner is a hardmask material selected from the group consisting of silicon oxide (SiO), silicon nitride (SiN), silicon oxynitride (SiON), silicon carbonitride (SiCN), silicon boronitride (SiBN), silicon borocarbide (SiBC), silicon boro carbonitride (SiBCN), and combinations thereof, wherein the fin liner is a different hardmask material from the bottom spacer layer.

14. The method of claim 13, further comprising forming a gate structure on the two or more vertical fins.

15. The method of claim 14, further comprising forming a dielectric separation region that physically and electrically separates the gate structure into two adjacent gate structures.

16. A vertical transport fin field effect transistor device, comprising:
two vertical fins on a substrate;
a bottom source/drain layer on the substrate;
a bottom spacer layer on the bottom source/drain layer;
an isolation trench between the two vertical fins, wherein the isolation trench extends through the bottom spacer layer and the bottom source/drain layer; and
a dielectric fill in the isolation trench, wherein the dielectric fill fills the isolation trench up to the bottom edge of the bottom spacer layer, such that a gap remains between adjacent sections of the bottom spacer layer.

17. The vertical transport fin field effect transistor device of claim 16, further comprising a gate structure on the two vertical fins, and a dielectric separation region that physically and electrically separates the gate structure into two adjacent gate structures.

18. The vertical transport fin field effect transistor device of claim 16, wherein the substrate and bottom source/drain layer are single crystal silicon, and the bottom spacer layer is a dielectric material selected from the group consisting of silicon oxide (SiO), silicon nitride (SiN), silicon oxynitride (SiON), silicon carbonitride (SiCN), silicon boronitride (SiBN), silicon borocarbide (SiBC), silicon boro carbonitride (SiBCN), and combinations thereof.

19. The vertical transport fin field effect transistor device of claim 18, further comprising a top spacer layer on the two adjacent gate structures.

20. The vertical transport fin field effect transistor device of claim 19, further comprising a top source/drain on each of the two vertical fins.
